(19) United States
(12) Patent Application Publication
(10) Pub. No.: US 2004/0041620 A1
(43) Pub. Date: Mar. 4, 2004

(54) LED driver with increased efficiency

(76) Inventors: Kevin P. D'Angelo, Santa Clara, CA (US); Richard K. Williams, Cupertino, CA (US); David Alan Brown, Los Gatos, CA (US)

Correspondence Address: Kevin D'Angelo, Advanced Analogic Technologies, Inc., 830 East Arques Avenue, Sunnyvale, CA, 94085-4519, US

(21) Appl. No.: 10/369,982

(22) Filed: Feb. 18, 2003

Related U.S. Application Data
(60) Provisional application No. 60/407,127, filed on Sep. 3, 2002.

(51) Int. Cl. H03K 3/01

(52) U.S. Cl. 327/534

(57) ABSTRACT

One of the several driver topologies provided by the present invention combines a charge pump, a DC/DC converter and a current source. The charge pump is unregulated and, as a result, has a high efficiency. The efficiency of the DC/DC converter is also high and the combination yields an overall efficiency of potentially more than 92%. A second topology combines a voltage regulator and a current source. The voltage regulator is connected to monitor the forward voltage of a driven LED and uses the forward voltage as a reference to produce an adaptive regulated voltage. This allows the voltage regulator to react to changes in the LED forward voltage by setting the regulated voltage to the lowest appropriate level. This second topology may also be configured to disable the voltage regulator when battery voltage exceeds a predetermined level.

### RELATED APPLICATIONS

This application claims the benefit of a U.S. Provisional Patent Application Serial No. 60/407,127 entitled “LED Driver with Increased Efficiency” filed Sep. 3, 2002. The disclosure of that provisional application is incorporated in this document by reference.

### TECHNICAL FIELD

The present invention relates to drivers used to power light emitting diodes (LEDs) and other devices. More particularly, the present invention relates to efficient drivers for white LED applications in portable electronic systems.

### BACKGROUND OF THE INVENTION

Extending battery life is one of the most important tasks faced by designers of portable electronic systems. This is particularly true for consumer electronics, such as cellular phones, digital cameras, portable computers and other handheld equipment. Designers of these products are faced with a continual need to reduce package size (and battery size) while increasing battery life to match or exceed competitive products.

White LEDs are commonly used to illuminate color displays in portable electronic systems. The forward voltage of these LEDs is usually higher than the voltage available from common battery chemistries and configurations. As a result, some form of driver is typically used to regulate voltage and current whenever white LEDs are powered by batteries. The relatively large amount of current handled by drivers of this type makes their efficiency (typically denoted η) a critical consideration for designers of portable electronic systems.

As shown in FIG. 1, a typical LED driver includes a voltage regulator and a current controller. The voltage regulator is generally a step-up type DC/DC converter circuit, employing either an inductor-based switching converter or a capacitive charge pump. For many applications, the current controller is a current source powered by the output of the voltage regulator and is placed in series with the LED and electrical ground. With this combination, multiple LEDs can be driven in parallel. Powering multiple parallel connected LEDs from a single-output current source, however, suffers from variation in LED brightness resulting from random mismatch in LED forward voltage V_{D}. FIG. 2 shows a similar topology where the current source has been replaced by a current setting resistor. Multiple LEDs driven in parallel is also possible using this approach, but the brightness variation problem is potentially exacerbated by both resistor and forward voltage mismatch.

To maximize efficiency and battery life, both the voltage regulator and the current controller must be optimized to minimize dissipate power dissipation. The efficiency of the current controller is equal to the ratio of its input and output voltages, and is optimized by lowering that ratio. Optimizing voltage regulator efficiency is more involved. As shown in FIG. 3, a typical LED driver places a regulated charge pump in series with a battery and current source (or other current controller). For this configuration, efficiency η is equal to V_{D} (the forward diode voltage) divided by V_{BAT} (the input power supply) times CP. In the case where a doubler regulated charge pump is used, CP is equal to 2. For typical applications where V_{D} and V_{BAT} are 3.5 volts, the resulting efficiency is 50%. Alternately, when a fractional charge pump is used, CP is equal to 1.5 and the resulting efficiency (for V_{D} and V_{BAT} equal to 3.5 volts) is 67%. For this reason, the use of a fractional charge pump is strongly indicated where efficiency is paramount. In either case, it is clear that the use of a regulated charge pump results in a significant reduction in efficiency.

As shown in FIG. 4A, a second method for driving LEDs places an inductor based DC/DC boost converter in series with a battery and current source (or other current controller). The driven LED's are configured in series, and the regulated voltage is equal to the number of LED's multiplied by the LED forward voltage V_{D} plus the voltage drop across the current controller. FIG. 4B shows a similar topology where the current source has been replaced by a current controlling resistor.

In practice, LED drivers of this type must be configured to generate relatively high regulated voltages, often in the range of twenty volts. For monolithic implementations, this means that the driver has to be implemented using a special high voltage wafer fabrication process. The high voltage process is typically expensive and unique and often prevents inductor based DC/DC boost converters from being implemented along with other functions in power management ASICs. Furthermore, the higher cost, increased noise and larger PC board areas makes boost converter based implementations undesirable, especially in portable products.

As the preceding paragraphs describe, available LED drivers have known disadvantages and there is a need for drivers that provide greater efficiency. This need is particularly relevant to portable electronic systems where increased efficiency is directly related to increased battery life.

### SUMMARY OF THE INVENTION

The present invention provides several topologies for driving white LEDs (and related devices) with high efficiency. One of the topologies combines a charge pump, a DC/DC converter and a current source. The charge pump is unregulated and, as a result, has a high efficiency. The efficiency of the DC/DC converter is also high and the combination yields an overall efficiency of potentially more than 92%. A second topology combines a voltage regulator and a current source. The voltage regulator is connected to monitor the forward voltage of a driven LED and uses the forward voltage as a reference to produce an adaptive regulated voltage. This allows the voltage regulator to react to changes in the LED forward voltage by setting the regulated voltage to the lowest appropriate level. This second topology may also be configured to disable the voltage regulator when battery voltage exceeds a predetermined level.

### BRIEF DESCRIPTION OF THE DRAWINGS

FIG. 1 is a block diagram of a prior art LED driver using a current source in series with a voltage regulator.

FIG. 2 is a block diagram of a prior art LED driver using a current setting resistor in series with a voltage regulator.

FIG. 3 is a block diagram of a prior art LED driver using a current source in series with a regulated charge pump.

FIG. 4A is a block diagram of a prior art LED driver using a current source in series with step up (Boost) converter.

FIG. 4B is a block diagram of a prior art LED driver using a current limiting resistor in series with step up (Boost) converter.

FIG. 5 is a block diagram of a LED driver using a current source in series with an unregulated charge pump followed by a step-down (Buck) DC-DC converter.

FIG. 6 is a block diagram of a LED driver that automatically adapts its regulated voltage output to reflect the forward current flowing through a driven LED.

FIG. 7 is a block diagram of the LED driver of FIG. 6 including circuitry to compensate for voltage overhead of an internal current source.

FIG. 8 is a block diagram of the LED driver of FIG. 7 including circuitry to disable an internal voltage regulator when an input battery voltage exceeds a predetermined level.

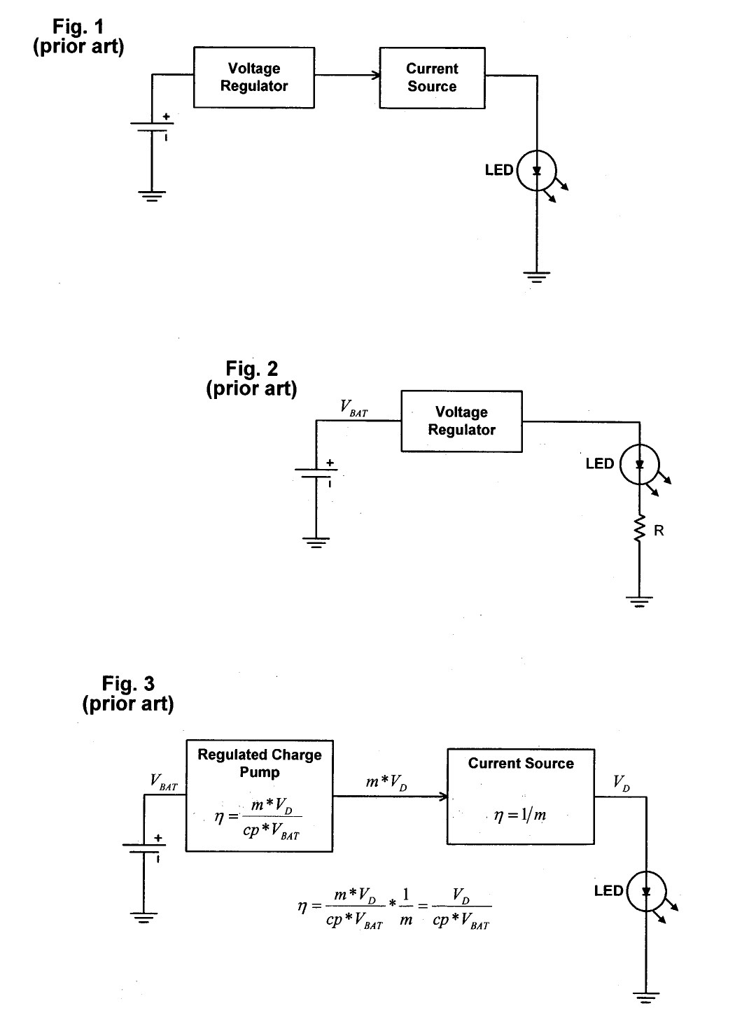

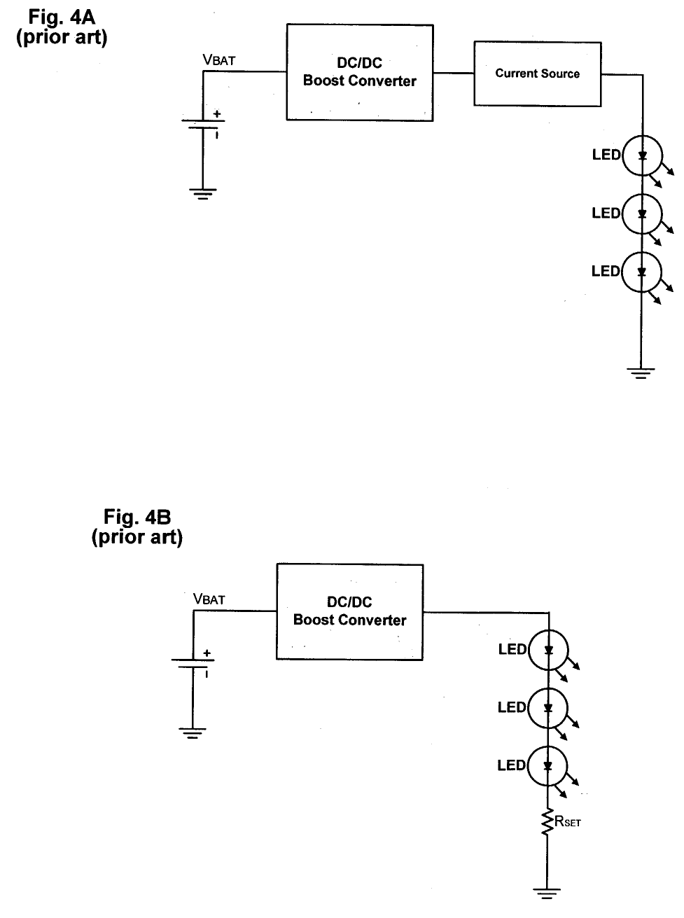

### DETAILED DESCRIPTION OF THE PREFERRED EMBODIMENTS

The present invention provides several topologies for driving white LEDs (and related devices) with high efficiency. The first of the topologies is shown in FIG. 5 and generally designated 500. As shown, topology 500 combines a charge pump 502, a Buck DC/DC converter 504 and a current source 506. These three components are placed in series between a power source, LED and ground. Charge pump 502 boosts the voltage available from the power source at the expense of introducing a degree of voltage fluctuation at the output of charge pump 502. Buck DC/DC converter 504 reduces the fluctuations to create a regulated voltage to supply current source 506. Current source 506 creates the forward current required to drive the LED. In general, the use of a Buck converter results in lower peak currents than a Boost converter for equivalent output currents. Topology 500 capitalizes on this by using the combination of charge pump 502 followed by followed by Buck DC/DC converter 504. The overall result is a topology that generates less noise than would be produced by a high voltage step up (boost) converter.

Unlike the charge pump of FIG. 3, charge pump 502 is unregulated, and, as a result, has an efficiency that can be as high as: η=95%. The efficiency of DC/DC converter 504 can be even higher at: η=97%. Combined with the efficiency of current source 506 (η=1 m) yields an overall efficiency of

$$η = \frac{0.95 * 0.97}{m}$$

(or potentially more than 92%) for topology 500.

Importantly, it is generally practical to combine both charge pump 502, and DC/DC converter 504 in the same package or even in the same silicon substrate. This makes topology 500 an appropriate choice for monolithic implementations in high efficiency portable electronic devices. Monolithic implementation is especially attractive in cases where DC/DC converter operates at a relatively high switching frequency allowing charge pump 502 and DC/DC converter 504 to be implemented using a single (and relatively small) inductor.

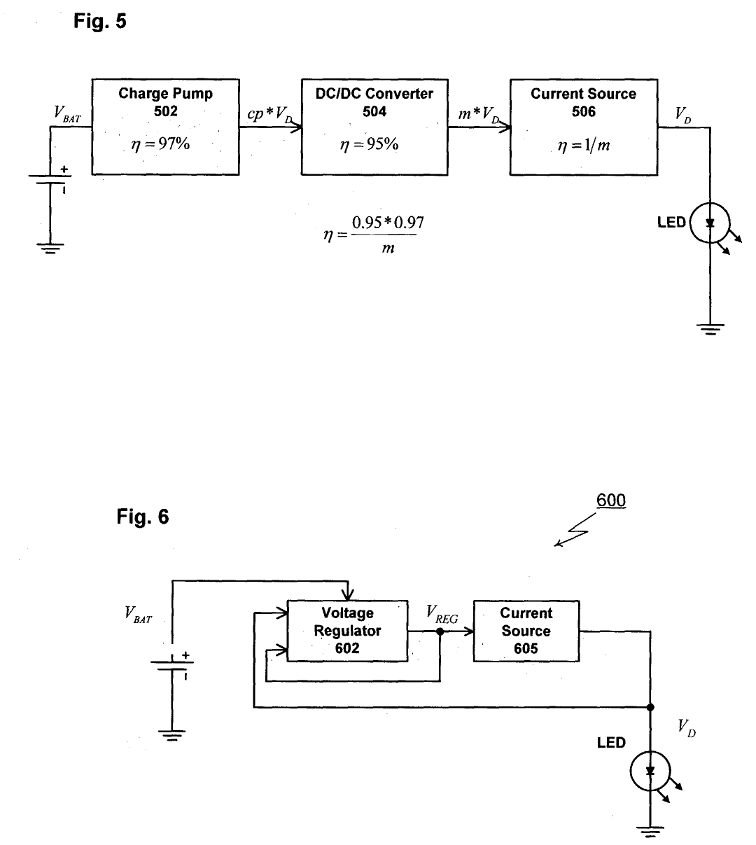

A second topology for driving white LEDs (and related devices) is shown in FIG. 6 and generally designated 600. Topology 600 is based on the observation that forward voltage of an LED increases as a function of forward current. As a result, the voltage used to drive an LED may be decreased (and power saved) whenever the LED is operating at less than its maximum current.

As shown in FIG. 6, topology 600 includes a voltage regulator 602 and a current source 604. As described for other topologies, these components are connected in series between a battery, LED and ground. The voltage regulator 602 is connected to monitor the forward voltage of the LED (V_{D}) and uses the forward voltage as a reference to produce an adaptive regulated voltage (V_{REG}). This means that voltage regulator 602 reacts to changes in V_{D} by setting V_{REG} at the lowest appropriate level.

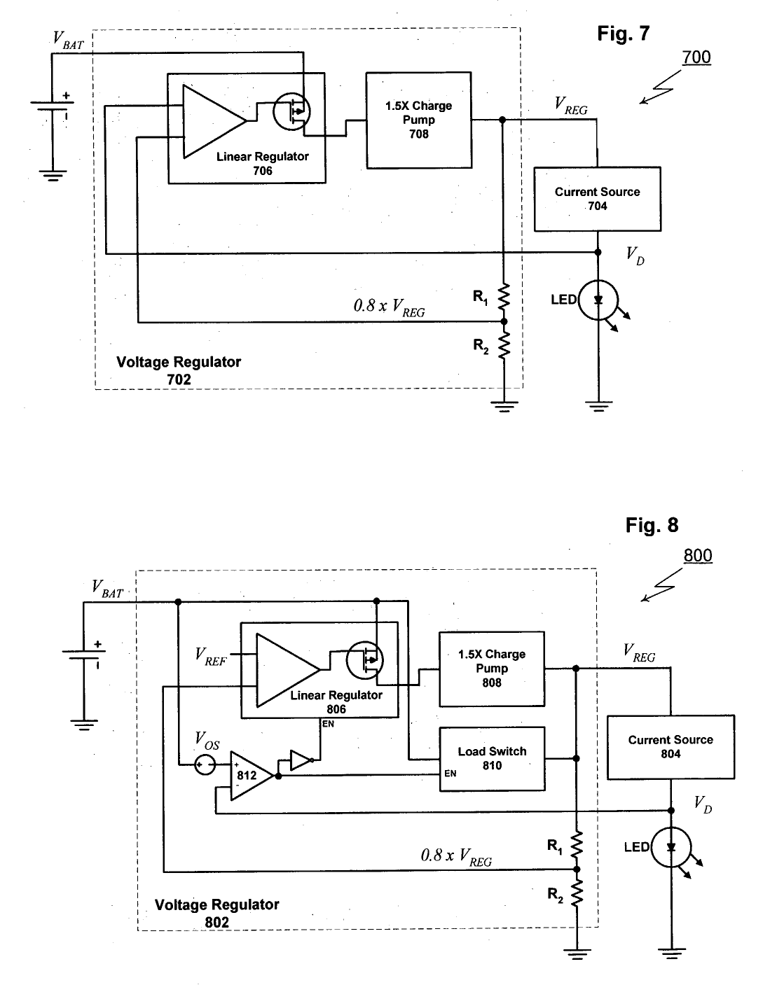

Within topology 600, current source 604 is used to drive the LED current. While doing this, current source 604 has an associated voltage overhead. The voltage overhead must be accounted for by voltage regulator 602. FIG. 7 shows a topology 700 that accomplishes this objective. As shown in FIG. 7, voltage regulator 702 includes a linear regulator 706 and a charge pump 708. Linear regulator 706 further includes a comparator driving a MOSFET. Other suitable components and topologies may also be used to implement voltage regulator 702.

Voltage regulator 702 also includes two resistors labeled R_{1 and R}₂. These two resistors form a voltage divider that multiples the regulated output of voltage regulator 702 (V_{REG}) by a predetermined percentage. The voltage divider output (in this case, eighty percent of V_{REG}) is used as the feedback voltage for voltage regulator 702. Multiplication of V_{REG} to form the feedback voltage works because the voltage overhead of current source 704 (like the forward voltage of the driven LED) increases as a function of the forward current. As a result, the LED forward voltage (V_{D}) can be calculated as a percentage of the regulated output of voltage regulator 702 (V_{REG}). For example, for the case shown in FIG. 7 (i.e., where the regulator feedback voltage is eighty percent of V_{reg}), a forward diode voltage (V_{D}) of 3.8 volts corresponds to a regulated voltage (V_{reg}) of 4.75 volts.

The batteries used to power portable electronic systems typically operate over a voltage range, starting from an initial high voltage and decreasing over time. For Lithium Ion battery cells, this range typically starts at 4.2 Volts and decrease to approximately 2.8 Volts. The forward voltage required to drive an LED (typically 3.5 Volts) falls almost in the middle of that range. This implies that there is a voltage range where the output of a Lithium Ion battery is sufficient to drive an LED without any form of voltage regulation. For example, if a typical forward LED voltage is 3.5 volts, and the voltage overhead required by the LED's current source is 250 mV, then any battery voltage greater than 3.75 volts can drive the LED without voltage regulation. The same no-regulation-range, with different boundaries, may also exist for other battery chemistries.

FIG. 8 shows a driver topology 800 that is optimized to distinguish between high battery voltages (where regulation is not required) and low battery voltages (where regulation is required). As shown in FIG. 8, topology 800 adds a load switch 810 and a comparator 812 to the components already described for topology 700. Load switch 810 is positioned in parallel with linear regulator 806 and fractional charge pump 808. The output of comparator 812 alternately enables either load switch 810 or the combination of linear regulator 806 and fractional charge pump 808. The inputs to comparator 812 are the LED forward voltage (V_{D}) and the difference between the battery voltage V_{BAT} and an offset voltage Vₒₛ, where Vₒₛ is the overhead required by current source 804.

During operation, comparator 812 enables load switch 810 and disables the combination of linear regulator 806 and fractional charge pump 808 whenever battery voltage (V_{BAT}) minus offset voltage (Vₒₛ) exceeds the LED forward voltage (V_{D}). This means that when battery voltage (V_{BAT}) is high (typically when V_{BAT} exceeds 3.75 volts) topology 800 operates without voltage regulation (load switch mode). As battery voltage (V_{BAT}) decreases, comparator 812 enables the combination of linear regulator 806 and fractional charge pump 808 and disables load switch 810. This means that when battery voltage (V_{BAT}) is low (typically when V_{BAT} is less than 3.75 volts) topology 800 operates with voltage regulation (voltage regulation mode). Importantly, using the LED voltage to decide which mode (load switch mode or voltage regulation mode) allows the same circuit to drive LED's with arbitrary forward voltages.

The efficiency of topology 800 is described by analyzing operation in two modes: load switch mode and voltage regulation mode. As previously described, the efficiency of topology 800 during operation in voltage regulation mode is defined as:

$$\begin{matrix}η = \frac{{P}_{out}}{{P}_{i n}} \\ = \frac{{V}_{REG} * {I}_{OUT}}{{V}_{BAT} * {I}_{OUT} * cp} \\ = \frac{{V}_{REG}}{1.5 * {V}_{BAT}}\end{matrix}$$

The efficiency of topology 800 during operation in load switch mode is a combination of the efficiencies of current source 804 and load switch 810. The efficiency of current source 804 is defined as:

$$\begin{matrix}η = \frac{{P}_{out}}{{P}_{i n}} \\ = \frac{{V}_{D} * {I}_{LED}}{{V}_{REG} * {I}_{LED}} \\ = \frac{{V}_{D}}{{V}_{REG}}\end{matrix}$$

and the efficiency of load switch 810 is defined as:

$$\begin{matrix}η = \frac{{P}_{out}}{{P}_{i n}} \\ = \frac{{V}_{REG} * {I}_{LED}}{{V}_{BAT} * {I}_{LED}} \\ = \frac{{V}_{REG}}{{V}_{BAT}}\end{matrix}$$

This yields a total efficiency for load switch mode of:

$$η = \frac{{V}_{D}}{{V}_{BAT}} .$$

The following table shows how the overall efficiency of topology 800 changes as a Lithium Ion battery is discharged:

[image]

Although particular embodiments of the present invention have been shown and described, it will be apparent to those skilled in the art that changes and modifications may be made without departing from the present invention in its broader aspects, and therefore, the appended claims are to encompass within their scope all such changes and modifications that fall within the true scope of the present invention.

What is claimed is:

1. A driver for an LED, the driver comprising:
an unregulated charge pump configured to increase the voltage available from a battery to create a boosted voltage;
a DC/DC converter configured to reduce fluctuations in the boosted voltage to create a regulated voltage; and
a current source operating at the regulated voltage and supplying a forward current to the LED.

2. A driver as recited in claim 1 wherein the unregulated charge pump and DC/DC converter are implemented monolithically within a single semiconductor substrate.

3. A driver for an LED, the driver comprising:
a current source operating at a regulated voltage and supplying a forward current to the LED; and
a voltage regulator configured to increase the voltage available from a battery to generate the regulated voltage, the voltage regulator configured to adaptively modulate the regulated voltage as a function of the forward voltage of the LED.

4. A driver as recited in claim 3 wherein the voltage regulator further comprises:
a fractional charge pump; and
a linear regulator driving the fractional charge pump.

5. A driver as recited in claim 4 wherein the output of the linear regulator is modulated based on a comparison of the forward voltage of the LED and a predefined fraction of the regulated output.

6. A driver for an LED, the driver comprising:
a current source supplying a forward current to the LED; and
a control circuit configured to supply a battery voltage to the current source whenever the forward voltage of the LED exceeds a predetermined level, the control circuit configured to supply a regulated voltage to the current source whenever the forward voltage of the LED does not exceed the predetermined level.

7. A driver as recited in claim 6 that further comprises: a voltage regulator configured to increase the voltage available from a battery to generate the regulated voltage, the voltage regulator configured to adaptively modulate the regulated voltage as a function of the forward voltage of the LED.

8. A driver as recited in claim 7 wherein the voltage regulator further comprises:
a fractional charge pump; and
a linear regulator driving the fractional charge pump.

9. A driver as recited in claim 8 wherein the output of the linear regulator is modulated based on a comparison of the forward voltage of the LED and a predefined fraction of the regulated output.
